(19) United States
(12) Patent Application Publication
(10) Pub. No.: US 2018/0364298 A1
(43) Pub. Date: Dec. 20, 2018

(54) SYSTEM AND METHOD FOR FORMAL CIRCUIT VERIFICATION

(71) Applicant: Onespin Solutions GmbH, Munich (DE)

(72) Inventors: Joerg Grosse, Munich (DE); Dominik Strasser, Munich (DE)

(21) Appl. No.: 15/626,674

(22) Filed: Jun. 19, 2017

(51) Int. Cl. G01R 31/28

(52) U.S. Cl. CPC G01R 31/2839; G01R 31/006; G01R 31/2844

(57) ABSTRACT

A system and computer-implemented method for calculation and display of a fault propagation path. The method identifies with a computing device a fault location in an electrical circuit under test, identifies with the computing device an observation point in the electrical circuit under test, computes with the computing device a fault path from the fault location to the observation point, and displays in a waveform viewer all signals in the fault path from the fault location to the observation point in order of their creation.

### CROSS-REFERENCE TO RELATED APPLICATIONS

None.

### STATEMENT REGARDING FEDERALLY SPONSORED RESEARCH OR DEVELOPMENT

None.

### BACKGROUND OF THE INVENTION

### Field of the Invention

The present invention relates to analysis and debugging of circuit designs, and more particularly, to formal verification of circuit designs with fault injection.

### Brief Description of the Related Art

Many industries, such as the automotive industry, have incorporated sophisticated electronics into their products and services. Welcome though these advances are, it is critical to understand that the electronic systems enabling these features also present countless new opportunities for things to go wrong if they are not adequately verified. A defective headrest video screen may be an irritation to a young passenger in the back seat, but a malfunctioning corrective steering system could cost the occupants of the vehicle their lives. These risks have caused industries to adopt stringent safety-related standards for electrical or electronic systems.

For example, the ISO 26262 standard governs the development of safety-related electrical and/or electronic (E/E) systems within road vehicles. ISO 26262 imposes stringent requirements that encompass the entire life cycle of a system, from concept phase to development, production, and decommissioning. It addresses the overall safety management process and covers relations with suppliers and interfaces for distributed development. The risk of liability is a clear driver of the adoption of the ISO 26262 standard, but there is more at stake: vehicle recalls in the millions and malfunctions leading to fatal car accidents not only cause economic damage, but also diminish the brand image of the companies involved. The standard specifies two types of component faults, which must be fully verified, systematic faults and random faults.

Systematic faults are introduced during component development, either through human error or tool/methodology malfunction. Systematic faults typically are handled through rigorous verification and the careful tracking of specific device requirements. Random faults occur during the actual operation of the device due to external effects. These faults must be safely handled by the circuitry within the device. This requires the use of fault handling capabilities built into the systems, which must in turn be verified to ensure that they will catch the vast majority of possible random faults.

Over the past several years, automotive suppliers have made substantial investments to meet ISO 26262 requirements, often leading to significant increases in development costs. Maturing the application of the standard and moving towards systematic and automated development methods is critical to achieve and sustain success.

Thanks to ease-of-use and capacity advances, formal-based verification methodologies have achieved recent wide adoption in the industry. Formal verification is widely recognized as a powerful technique to uncover hardware design bugs that might otherwise escape simulation-based verification and lead to systematic failures. A key characteristic of formal tools is the ability to examine design behavior exhaustively, without the need for input stimuli, and prove that the design never deviates from its intended function, as specified by a property or assertion. Even for simple designs, simulation tools cannot achieve this level of precision. Formal tools have multiple applications for both systematic and random fault verification.

Failures happen when an element of a system no longer performs its required function. They are caused by errors, such as a hardware component not behaving as expected. Errors are caused by faults either in the design of the device, or occurring during its operation. Examples of such errors in an automotive environment and possible causes are shown in FIG. 1.

ISO 26262 defines two categories of failures: systematic and random. Systematic failures can originate in both hardware and software, and have a deterministic relation to certain causes or faults, for example, specification or coding mistakes in software or hardware code. These faults affect all manufactured components and must be avoided. Random failures originate only in hardware and occur in an unpredictable fashion that generally follows a probability distribution. They cannot be traced back to specific problems and are expected to occur during system operation. A good example is radiation corrupting a DRAM memory during device operation. Note that random component failure might be seen as a systematic fault at the vehicle level.

ISO 26262 prescribes the use of safety measures to avoid systematic faults and safeguard against random hardware faults. Formal tools can play a significant role in implementing safety measures efficiently, and indeed are central in many safety-critical development flows.

Rigorous development processes are key to reducing the risk of systematic faults in a system, introduced through human error. Advanced hardware development flows employ many tools and methods to detect issues as early as possible, plan verification activities, and track progress. ISO 26262-8 clause 6, however, demands an accurate tracing of requirements throughout the relevant development steps. The ultimate goal is to ensure that a product satisfies its safety requirements. This involves tracking a large number of bidirectional, many-to-many relationships, mapping requirements through design features to verification plan elements, and finally, to feedback test coverage data to all these documents.

For the functional verification of Register Transfer Language (RTL) models, engineers apply a variety of techniques, including directed and random coverage-driven simulation tests. Structural and functional coverage metrics are used to track progress and highlight gaps in the verification plan or specification documents.

Simulation-based verification environments often rely on centralized checks and thus suffer from low design observability. Even when a test activates a design feature that is not correctly implemented, the erroneous behavior could go undetected unless it propagates to an observation point (or checker). ISO 26262 specifies that requirements must be individually tested and this testing process carefully tracked, as shown in FIG. 4. For simulation, typically this involves creating individual, directed tests, which can be laborious and error-prone.

Assertion-based verification (ABV) is a well-established technique that addresses this issue. Assertions are flexible and can concisely express the expected design behavior at both low and abstract levels. They are distributed and always-on checkers that—crucially, in this context—may map more directly to requirements. Another key benefit of ABV is that formal tools can leverage assertions and examine them under all relevant stimuli scenarios. Moreover, with adequate tools and methodology, it is also possible to construct a set of non-overlapping assertions capturing all design requirements. Assertions, specifically end-to-end properties, can be easier to map to requirements through the implementation and verification plan. By leveraging ABV, the entire verification tracking mechanism is simplified through direct correlations between requirements and tests.

Safety mechanisms are a class of safety measures built into the device, intended to detect faults or control failures, as shown in FIG. 2. ISO 26262 may require the use of safety mechanisms to detect, and possibly correct, the effects of some random hardware faults. Safety mechanisms are implemented in both software and hardware, and their ultimate goal is to reduce the occurrence of random failures that could lead to violations of safety goals.

Software-based mechanisms include routines that run periodically to detect hardware errors, mostly caused by permanent faults or latent transient faults. Another example is redundant software performing the same operation multiple times and comparing results. One of the challenges is to detect as many faults as possible, while limiting the size and run time of the code.

Redundancy is the foundation of many hardware-based safety mechanisms. Common techniques include: having a processor core running in lockstep with a duplicate core and comparing results; duplication or even triplication of critical modules or configuration registers with the addition of majority-voting logic (triple modular redundancy); failsafe encoders and decoders to protect memories or bus transactions (EDC/ECC); detecting and correcting single-bit errors; and detecting double bit errors.

Hardware-based safety mechanisms significantly complicate all stages of development, including physical implementation, as they increase circuit area and make it harder to achieve the target clock frequency.

The development of hardware safety mechanisms must follow a rigorous process to avoid systematic faults. The functional verification of the RTL model implementing a safety mechanism is a critical activity, as mistakes could lead to hardware that causes dangerous situations rather than preventing them. ISO 26262-5 addresses all hardware-specific development activities, and their requirements include a quantitative analysis of the effectiveness of safety mechanisms. Faults are classified according to the categories safe, single point, residual and multipoint. Safe faults are faults that are not in the safety relevant parts of the logic or are in the safety relevant logic but are unable to impact the design function, i.e., they cannot violate a safety goal. Single point faults are dangerous because they can violate a safety goal and there is no safety mechanism to protect against them. Residual faults also are dangerous because they can violate a safety goal and escape the safety mechanism. Multipoint faults can violate a safety goal but are observed by a safety mechanism. The multipoint faults can be subclassified as “detected,” “perceived” and “latent.”

Within the present context, multipoint faults and safe faults are not dangerous. However, identifying them is challenging. Safety-critical hardware may include a variety of safety mechanisms, and engineers must analyze the effects of several fault types on millions of potential fault locations interconnected by complex logic.

It is not trivial to confidently mark a fault as safe. Without adequate tools, only experts with intimate knowledge of the hardware can reach this conclusion. Similarly, expert engineering effort might be required to develop simulation workloads that can demonstrate the ability of a safety mechanism to observe a fault. Hardware teams for ASIL C or ASIL D applications have to demonstrate that only an extremely low proportion of dangerous faults can have an operational effect on their designs. Consequently, the ability to identify safe and multipoint faults automatically is critical to achieve this goal efficiently.

Fault injection is an established technique used to understand the effects of faults on fault-tolerant systems. ISO 26262 highly recommends the use of fault injection during the development of safety-critical hardware. To take into account operating conditions and full system interactions, fault injection should be performed on a system prototype. For example, instruments can be used to create heavy ion radiation, electromagnetic interference, power supply disturbances, or software issues that corrupt the content of memories or architecturally visible registers. Haissam Ziade, Rafic Ayoubi, and Raoul Velazco, “A Survey on Fault Injection Techniques. The International Arab Journal of Information Technology,” Vol. 1, No. 2, July 2004. However, this method is challenging in terms of cost, controllability and observability of the system, and development schedule. Model-based fault injection can be performed early in the development flow and provides finer control over the system without being invasive: that is, the fault injection mechanism has no effect on the system other than the faults it injects. Ashish Darbari, Bashir Al Hashimi, Peter Harrod and Daryl Bradley, “A New Approach for Transient Fault Injection using Symbolic Simulation,” 14th IEEE International On-Line Testing Symposium 2008.

The safety analysis of complex automotive SoCs including a variety of safety mechanisms poses many challenges. Precisely identifying the safety-critical implementation logic is no small matter. The number of fault locations to consider can be on the order of millions. Several types of permanent and transient faults can be injected in a fault location, and the effect of a number of simultaneous faults might have to be analyzed under different workloads. The number of relevant fault scenarios is huge.

In recent years, there has been progress in the availability of tools to perform fault injection on hardware models. While existing simulators can perform clumsy fault injection by using generic interface commands, the re-emergence of fault simulators, previously designed for the qualification of manufacturing tests, has brought substantial benefit to engineers in terms of enabling precise metrics and debug.

Fault propagation analysis is used to classify faults and derive diagnostic coverage metrics. This task may be performed on RTL models but, according to ISO 26262 stipulations, will ultimately have to be performed on a model that is as close as possible to the actual hardware and that can provide good correlation not only at the logical level, but also on physical parameters, such as circuit area. This requires running the analysis on gate-level netlists.

Fault simulation is a standard approach to determine fault metrics. Fault simulators inject faults and analyze their propagation under user-defined input stimuli. Faults causing errors that are detected by a safety mechanism contribute to achieving the desired detection ratio. Faults not activated or propagated by the input stimuli consume a large proportion of the simulation cycles, while remaining in the “potentially propagatable” group. These faults are difficult to debug when considering stimulus improvements. In fact, a significant portion of them could be safe or “non-propagatable.” Safe faults can never lead to a malfunction of the system, regardless of its state. Engineers may use “expert judgment” arguments to mark some faults as safe, thus increasing diagnostic coverage.

Even modern fault simulators, however, have inherent shortcomings. The analysis of faults is inefficient with respect to both the fault scenarios (some simulators requiring one run per scenario) and the specific workload, or input vectors, applied to the model (simulators only execute one workload at a time). Moreover, to achieve the target ASIL diagnostic coverage—the metric specifying the number of safe faults—engineers may have to manually identify safe faults, create complex tests that can activate and propagate tricky faults to safety logic, and define the boundaries of safety-critical logic. These tasks are effort-intensive, error-prone, and intrinsically incomplete.

Formal verification is widely recognized as a powerful technique to uncover hardware design bugs that might otherwise escape simulation-based verification and lead to systematic failures. A key characteristic of formal tools is the ability to examine design behavior exhaustively, without the need for input stimuli, and prove that the design never deviates from its intended function, as specified by a property or assertion. Even for simple designs, simulation tools cannot achieve this level of precision. Formal tools have multiple applications for both systematic and random fault verification.

“Formal methods” refers to mathematically rigorous techniques and tools for the specification, design, and verification of software and hardware systems. While formal property-checking tools have been available for decades, in the last ten years, thanks to advances in ease-of-use and capacity, formal-based methodologies have achieved wide adoption in the semiconductor industry. Formal verification is widely recognized as a powerful technique to uncover hardware design bugs that might otherwise escape simulation-based verification and lead to systematic failures.

A key characteristic of formal tools is the ability to examine design behavior exhaustively, without the need for input stimuli, and prove that the design never deviates from its intended function, as specified by a property or assertion. Even for simple designs, simulation tools cannot achieve this level of precision. A range of hardware development tasks has been improved through the use of appropriate formal-based solutions (or apps). These range from RTL design exploration and formal linting to the end-to-end verification of critical modules.

Another key characteristic of formal tools, particularly relevant to safety-critical applications, is the ability to finely control the injection of faults into hardware models and analyze their sequential effects. Crucially, formal tools have the potential to perform this task very efficiently, in terms of both user effort and computational demands, and non-invasively (no need for code instrumentation steps).

As part of the safety verification process, it often is necessary to understand how faults propagate through an integrated circuit. Examples of prior systems and methods for waveform or propagation analysis are disclose din U.S. Pat. No. 8,630,824 and U.S. Patent Application Publication No. 2016/0283628.

Conventional fault propagation systems and methods often display a golden design and the faulty design next to one another, showing the value of signals in the golden design versus the design with the fault injected. Such conventional environments might be able to list all internal signals where the values are different between the golden design and the faulty design but they typically would display signals which are different, including signals that are irrelevant to the fault debug.

### SUMMARY OF THE INVENTION

In a preferred embodiment, the present invention is a system and method for analysing faults and displaying a fault propagation path inside a waveform debugger. In the system, a computing device having processor and memory has a fault injection module or application for injecting fault into the circuit design. The computer device further has a fault propagation module or application and/or a fault detection module or application for detecting faults and tracking the propagation of the faults (e.g., signals) through the circuit design. A fault location for injecting a fault and an observation point are identified. The observation point in the circuit design is a point where errors can have a dangerous impact. The system has a display for displaying a signal path in an ordered list from the fault location to the observation point(s) whereby each signal inside the path has been impacted by the fault. “Impacted” refers to the value in the design between different than what the value would be in a golden design. Only one waveform is shown for a given signal. The impacted signals are shown in a different color (e.g., red) than the non-impacted signals. The signals are displayed in the timing domain, which results in a “stepladder” in a different color showing host the fault moves forward from one signal to the next.

In another preferred embodiment, the present invention is a system and computer-implemented method for calculation and display of a fault propagation path. The method includes the steps of identifying with a computing device a fault location in an electrical circuit, identifying with said computing device an observation point in the electrical circuit, computing with said computing device a fault path from said fault location to said observation point; and displaying in a waveform viewer all signals in said fault path from said fault location to said observation point in order of their creation. The step of computing a fault path may comprise computing the shortest path of impacted signals from the fault location to the observation point. The step of computing the shortest fault path may comprise computing the shortest path in terms of the number of signals, computing the shortest path in terms of the number of instances or computing the shortest path in terms of the number of registers. In an alternative embodiment, a deviation or alteration may be added to the shortest path and the deviated or altered resulting path may be displayed.

The step of computing a fault path may comprise (a) entering an observation point in a current signal list, (b) comparing each signal on the current signal list with an impacted signal list, (c) for each compared signal, if the signal is not on the impacted signal list, doing nothing with respect to that signal, (d) for each compared signal, if the signal is on the impacted signal list, checking if the signal is the fault location, (e) for each compared signal on the impacted signal list, if the signal is the fault location skipping to step (h), (f) for each compared signal on the impacted signal list, if the signal is not the fault location adding the fanin signals of the signal to a next current signal list and storing the signal as the parent of the added fanin signals, (g) making the next current signal list the current signal list and returning to step b, (h) setting the fault locations at the path signal, (i) determining if the path signal has a parent signal, (j) if the path signal has a parent signal, using the parent a new path signal, storing the new path signal in a path list, and returning to step i for the new path signal, and (k) if the path signal does not have a parent signal, outputting the path of impacted signals as the shortest fault path to the waveform viewer.

Still other aspects, features, and advantages of the present invention are readily apparent from the following detailed description, simply by illustrating a preferable embodiments and implementations. The present invention is also capable of other and different embodiments and its several details can be modified in various obvious respects, all without departing from the spirit and scope of the present invention. Accordingly, the drawings and descriptions are to be regarded as illustrative in nature, and not as restrictive. Additional objects and advantages of the invention will be set forth in part in the description which follows and in part will be obvious from the description, or may be learned by practice of the invention.

### BRIEF DESCRIPTION OF THE DRAWINGS

For a more complete understanding of the present invention and the advantages thereof, reference is now made to the following description and the accompanying drawings, in which:

FIG. 1 is a diagram illustrating various types of faults that may occur in a safety critical system and exemplary results of such faults.

FIG. 2 is a diagram illustrating a general safety critical system having a hardware safety mechanism.

FIG. 3 is a system architecture diagram of a system for analyzing and displaying fault propagation in accordance with a preferred embodiment of the present invention.

FIG. 4 is a flow chart of a method for analyzing and displaying fault propagation in accordance with a preferred embodiment of the present invention.

FIG. 5 is an illustration of a display of a system for analyzing and displaying fault propagation in accordance with a preferred embodiment of the present invention.

FIG. 6 is a flow diagram illustrating signal flow through a system for analyzing and displaying fault propagation in accordance with a preferred embodiment of the present invention.

FIG. 7 is a diagram illustrating a fault path calculation in accordance with a preferred embodiment of the present invention.

FIG. 8 is a flow diagram of a method for computing a fault path in accordance with a preferred embodiment of the present invention.

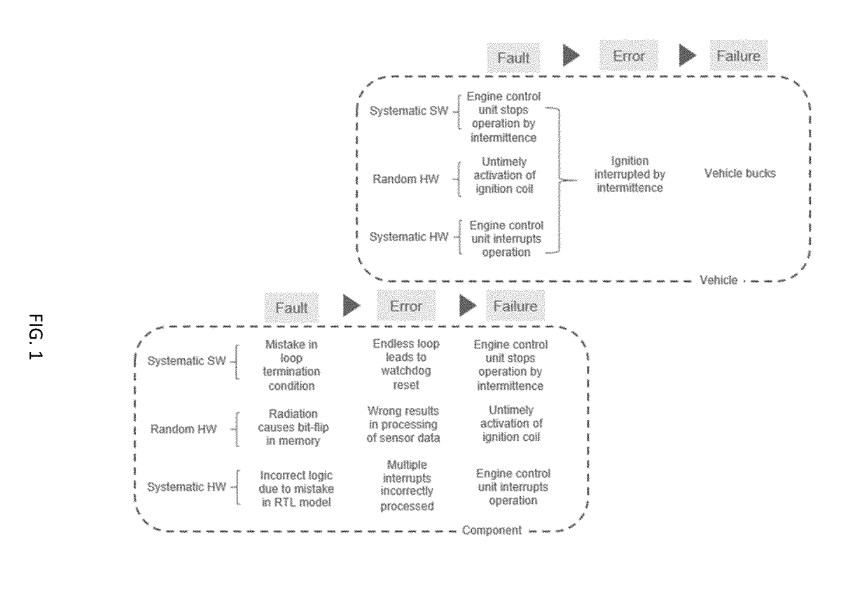

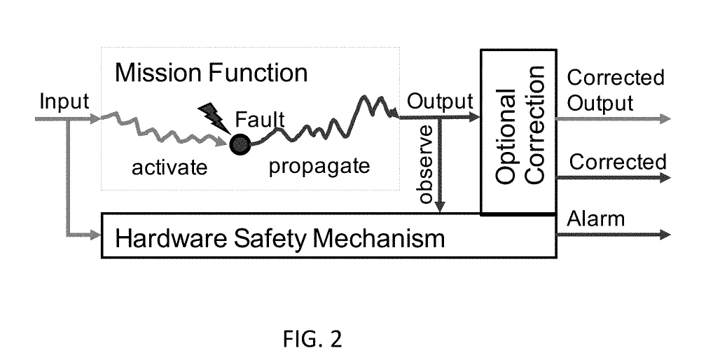

### DETAILED DESCRIPTION OF THE PREFERRED EMBODIMENTS

Hardware safety mechanisms are necessary to guarantee determinist SoC behavior in the event of random faults. Typically, implementing hardware safety mechanisms involves some form of redundant logic that does not directly contribute to the implementation of the circuit's mission function. In the presence of faults, this logic becomes truly active and is responsible to detect, possibly correct, and report these faults to relevant part of the system. Functional verification planning, tracking and execution of both mission and safety functions is critical to meet the strict demands of safety standards. Key aspects in the verification of safety functions are that they (1) do not interfere with the hardware functionality under normal operation, (2) detect faults and correctly route information (alarm, fault corrected, etc.) to the relevant part of the system and (3) improve system availability by correcting the effect of some faults.

Safety mechanisms bring another dimension to the already complex and time-consuming task of functional verification. There are countless fault scenarios to examine and engineers often need a dedicated test environment to handle fault injection, related checkers, and coverage data.

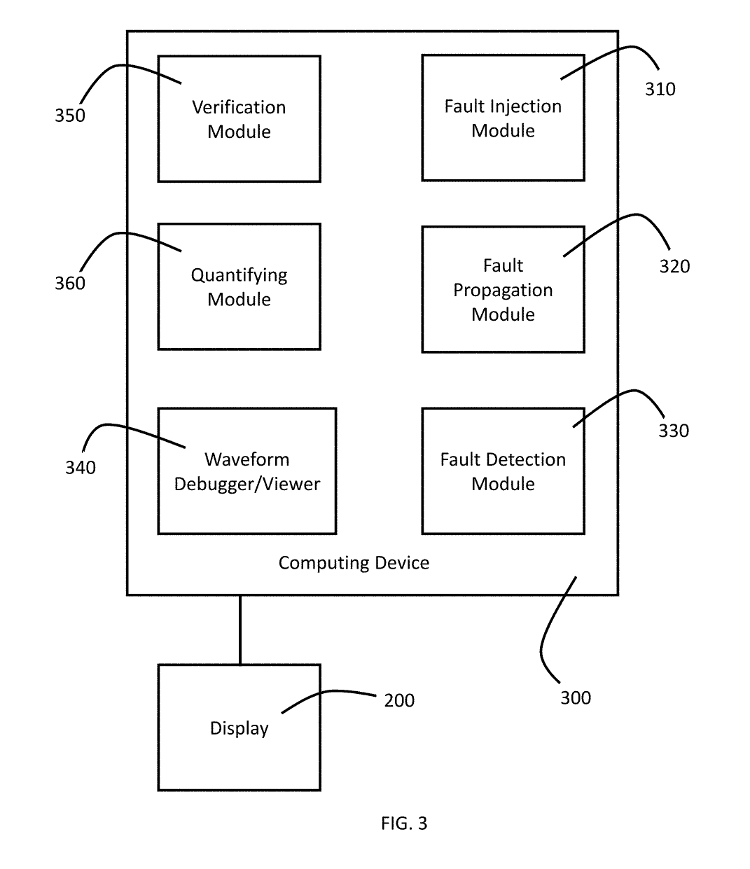

A general architecture for a system and method for analyzing and displaying fault propagation path in accordance with a preferred embodiment of the present invention is shown in FIG. 3. The system includes a computing device 300, which may be a computer or server having one or more processors, a memory and a non-transitory storage medium such as a hard drive or solid state drive. The computing device 300 has a fault injection module 310, a fault propagation module 320, a fault detection module 330, and a waveform debugger 340. The computing device may have other modules or applications such as a verification module 350 or a Quantifying module 360. The system further has a display 200. The fault injection module or application 310 provides a simple and flexible interface to define and inject fault scenarios, with no need to change the design, go through complex code-instrumentation steps, or develop a dedicated verification environment.

Fault propagation analysis comprises the injection of faults into the gate level models of integrated circuits during verification to prove that faults will be detected by a safety mechanism. These gate level models can be complex and contain numerous possible fault scenarios. In order to satisfy hardware safety goals, the number of “dangerous non-detected” faults must be minimized.

Fault simulation is a standard approach to determine fault metrics. Faults are stimulated and propagated to observation points, to ensure detection by a safety function. Any faults not activated or not propagated by the functional stimulus consume a high proportion of the simulation cycles. They are also difficult to debug when considering stimulus improvements. Thus these faults often remain in the “not detected” group, detracting from the desired detection ratio.

A fault scenario can be seen as a set of faulty variants of the original design, the design under test (DUT). The first element of a fault scenario is the set of bit-level design signals where faults shall be injected. The other elements define when and which types of faults shall be injected. The original design corresponds to the particular fault scenario of no faults being present.

Users have the flexibility of defining custom fault scenarios, or pick predefined ones. A simple scenario could describe the injection of stuck-at-0 faults on all bits of a number of design signals, all the time. A custom scenario could describe the injection of a SEU fault, e.g. a bit-flip, in an arbitrary bit of a memory location, occurring only once and coinciding with some other condition, for example a memory read on a specific address. User assertions can be associated with specific fault scenarios, and powerful proof strategies are automatically setup to handle the simultaneous exhaustive verification of huge fault populations in large and complex designs. Moreover, dedicated debug features speed up the daunting task of examining assertion failures on fault-injected designs, where things can get quite confusing. Finally, the quantify module can measure the coverage of the overall set of assertions at the push of a button and expose both mission and safety-related functional areas that have verification gaps.

Faults can be classified as propagatable and non-propagatable. Non-propagatable faults can never lead to a malfunction of the system regardless of its state. Hence they are safe and can be removed from the dangerous fault list, improving the fault metric. This is where formal technology can be effectively applied in an automated way using the Fault Propagation Module 320. The Fault Propagation Module 320 automatically identifies non-propagatable faults, allowing their safe elimination prior to simulation, thereby cutting on simulation and debug time while increasing the nominal fault coverage Any know method for identifying non-propagatable faults may be used.

The Fault Propagation Module 320 is applied to the overall fault population both prior to and after fault simulation. The Fault Propagation Module 320 has a “fast mode” and a “deep mode.” Operating in a “fast mode” the Fault Propagation Module 320 is run pre-simulation, utilizing formal analysis to efficiently identify non-propagatable faults, thereby enabling the desired fault detection ratio to be rapidly achieved while avoiding unnecessary effort. These faults may be pruned from the fault list without the requirement for fault simulation test vectors. The entire fault-simulation process is significantly accelerated through the removal of this class of faults from those that need to be run in fault simulation.

Operating in a “deep mode” the Fault Propagation Module 320 can be used to analyze non-propagatable faults identified during a simulation-based fault injection process to either improve the safety mechanism or to classify them as safe. This automated step greatly reduces the manual effort required post-fault simulation to identify any remaining dangerous faults. The analysis is accomplished without modification of the netlist—a requirement of the certification standards.

The only required input is a gate or RTL model for the circuit under test. The system identifies fault locations where it already performs optimizations such as net collapsing to avoid duplications. Alternatively, a fault list or design areas of interest indication may be provided, which is used by the tool to refine the fault list.

Furthermore, an initial design state may be loaded to allow a context analysis. Such an analysis can be important to understand how faults behave when injected at a certain execution time.

After fault list creation, the system performs a fully automated formal analysis to identify non-propagatable faults. After the analysis, the non-propagatable, as well as the potentially propagatable faults can be written into a simple CSV formatted text file for further processing. In addition, an analysis summary report is generated. A fast statistical analysis may also be performed where the fault list is sampled rather than analyzing all faults.

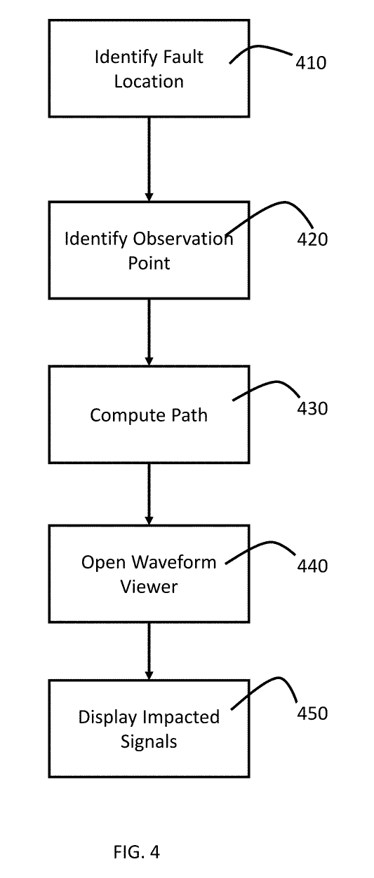

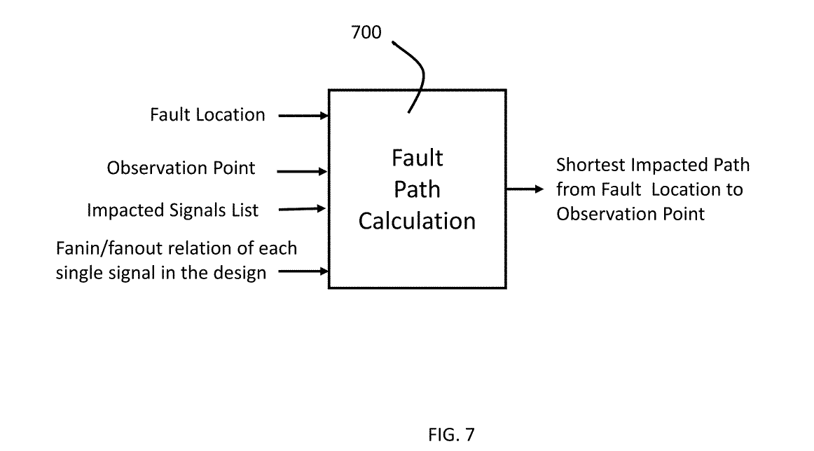

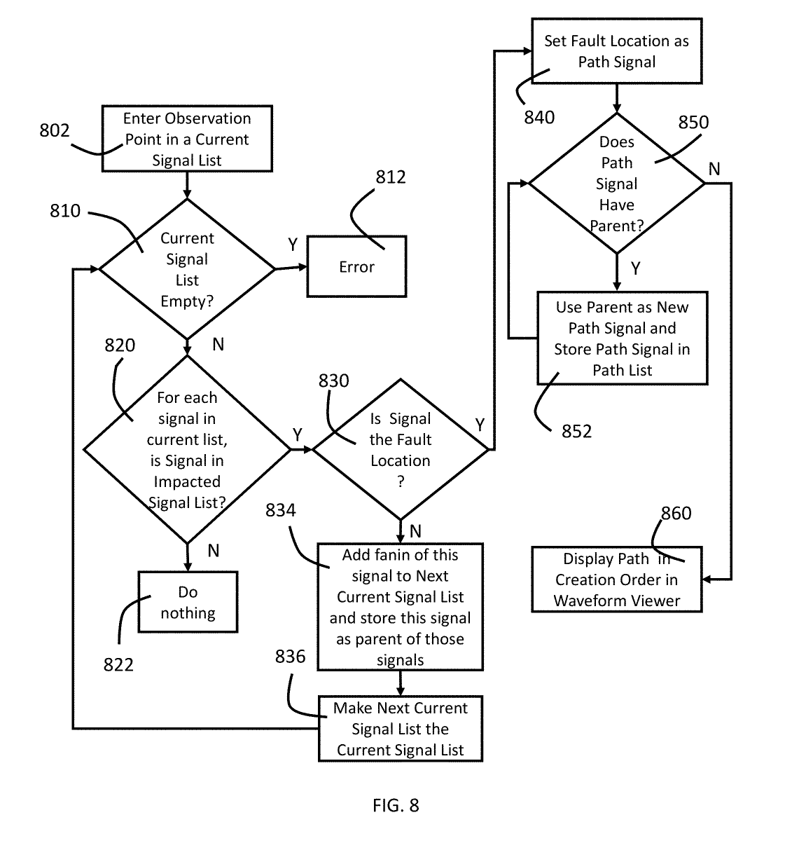

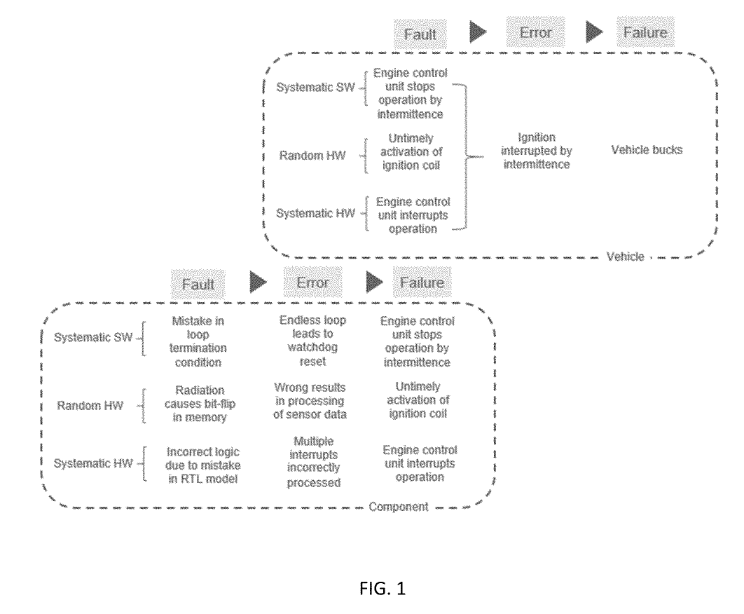

In the method of a preferred embodiment of the present invention, as shown in FIG. 4, the system identifies 410 a fault location for injecting a fault and identifies 420 an observation point. The observation point in the circuit design is a point where errors can have a dangerous impact. The system computes 430 the fault path (explained later in further details with reference to FIGS. 7 and 8). The system then opens 440 a viewer in the waveform debugger 340. The system 300 then displays 450 on the display 200 an impacted signal path in an ordered list from the fault location to the observation point whereby each signal inside the past has been impacted by the fault. “Impacted” refers to the value in the design between different than what the value would be in a golden design. In alternative embodiments, a plurality of observation points may be used, for example, if the fault propagates to more than one observation point.

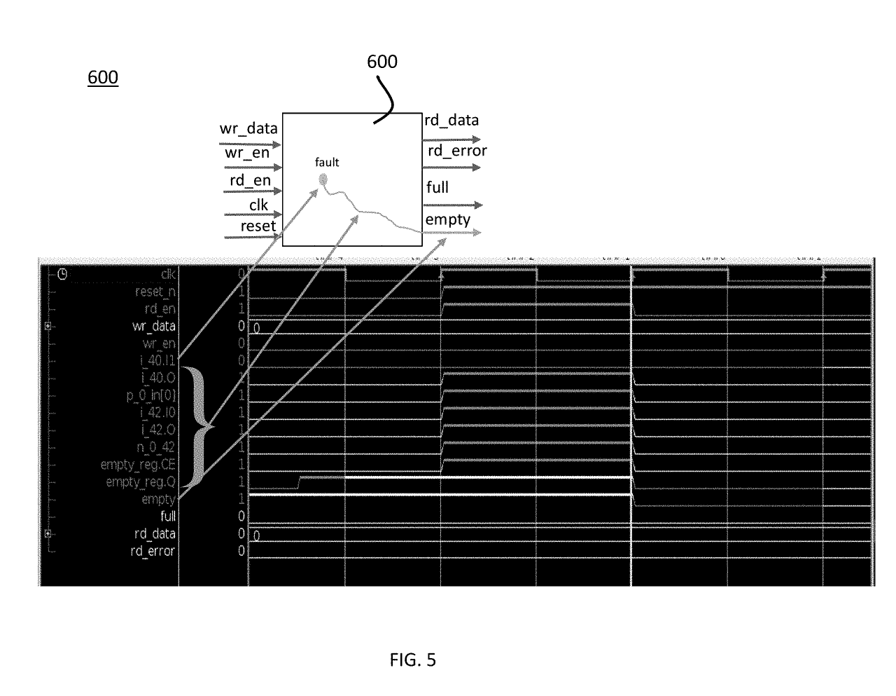

As shown in FIG. 5, only one waveform is shown for a given signal. The impacted signals are shown in a different color (e.g., red) than the non-impacted signals. Indicators other than color, such as line thickness, type of line (e.g., dashed, dotted, etc.), markings on the lines (e.g., x's, *'s, etc.) or any other visual indicator, may be used. Preferably, the signals are shown in a different color only when the value of the golden and faulty signal is different. Also, as an alternative to the display shown in FIG. 5, the values of the golden and fault signals could be placed next to each other onto a given single wave. Displaying two values can be particular useful when the displayed signal is not a single bit. The signals are displayed in the timing domain, which results in a “stepladder” in a different color showing host the fault moves forward from one signal to the next. Different colors may be used in the display to show how the fault moves forward from one signal to the next. As also shown in FIG. 5, it may be beneficial to display the inputs of the device before the signal and the outputs of the device after the signal. In the alternate embodiment having multiple observation points, data and graphs for a plurality of observation points can be shown on the display or waveform viewer.

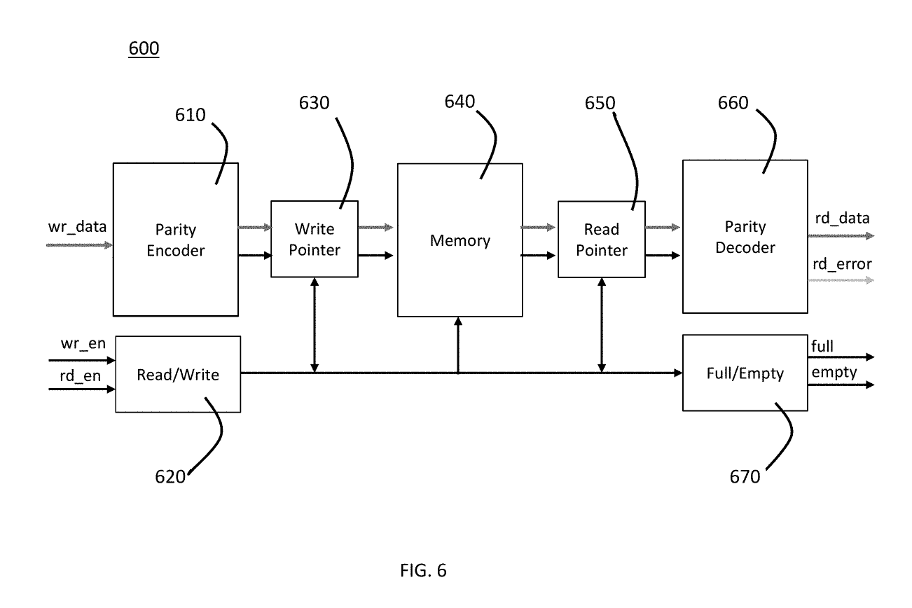

An exemplary architecture 600 for verification of hardware safety mechanisms is shown in FIG. 6. The system has a parity encoder 610, read/write 620, write pointer 630, memory 640, read pointer 650, parity coder 660 and full/empty 670.

As shown in FIG. 7, the inputs for the fault path calculation 700 are start point (fault location) and end point (observation point), a list of signals that were impacted by the fault as calculated from a counterexample (the complete list of impacted signals), and the fanin/fanout relation of each single signal in the design. The output of the fault path calculation is the shortest path from the start point to the end point. The shortest path can be in terms of the number of signals, the number of instances or a number of registers/states. Instances can have different numbers of signals attached to them. An instance is typically a cell (like an AND call or FlipFlop cell). The shortest path from the start point to the end point may not be the absolute shortest path but may include any deviations or alterations between the start point and the end point. Deviations or alterations may added by any means such as FlipFlop and the like.

An exemplary method for computing a fault path in accordance with a preferred embodiment of the present invention is described with reference to FIG. 8. The inputs for the calculation are shown in FIG. 7. An Observation Point is entered into a Current Signal List at 802. If this is the first iteration, the Current Signal List may have only one signal (the Observation Point). If it is a later iteration, the Current Signal List will have a plurality of signals. At 810, if the Current Signal List is empty, the system knows there is an error and appropriate error notification is undertaken at step 812. If the Current Signal List is not empty at 810, the system determines at 820 for each signal in the Current Signal List whether that signal is on the Impacted Signal List. If a particular signal is not on the Impacted Signal List, the system does nothing at 822 with respect to that signal. If a particular signal is on the Impacted Signal List, the system checks at 830 whether the signal is the Fault Location. If it is not the Fault Location, the system adds the fanin of this signal to a Next Current Signal List and stores the signal as the parent of those fanin signals at 834. Once all signals on the Current Signal List have been checked, the system makes the Next Current Signal List the Current Signal List at 836 and then returns to 810. If a signal is the fault location at step 830, the system sets the fault location as the path signal at 840. The system than determines at 850 whether the path signal has a parent. If yes, the system sues that parent as a new Path Signal and stores that Path Signal in the Path List at 852. The system then returns to step 850. If the Path Signal does not have a parent, the system displays the path in creation order in a waveform viewer at 860. In this way, the shortest path from the fault location to the observation point is determined and displayed.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

What is claimed is:

1. A computer-implemented method for calculation and display of a fault propagation path comprising:
identifying with a computing device a fault location in an electrical circuit;
identifying with said computing device an observation point in the electrical circuit;
computing with said computing device a fault path from said fault location to said observation point; and
displaying in a waveform viewer all signals in said fault path from said fault location to said observation point in order of their creation.

2. A computer-implemented method for calculation and display of a fault propagation path according to claim 1, wherein the step of computing a fault path comprises:
computing the shortest path of impacted signals from the fault location to the observation point.

3. A computer-implemented method for calculation and display of a fault propagation path according to claim 2, wherein the step of computing the shortest fault path comprises:
computing the shortest path in terms of the number of signals.

4. A computer-implemented method for calculation and display of a fault propagation path according to claim 2, wherein the step of computing the shortest fault path comprises:
computing the shortest path in terms of the number of instances.

5. A computer-implemented method for calculation and display of a fault propagation path according to claim 2, wherein the step of computing the shortest fault path comprises:
computing the shortest path in terms of the number of registers.

6. A computer-implemented method for calculation and display of a fault propagation path according to claim 2, wherein the step of computing the fault path further comprises:
adding a deviation or alteration to the shortest path.

7. A computer-implemented method for calculation and display of a fault propagation path according to claim 1, wherein the step of computing a fault path comprises:
a. entering an observation point in a current signal list;
b. comparing each signal on the current signal list with an impacted signal list;
c. for each compared signal, if the signal is not on the impacted signal list, doing nothing with respect to that signal;
d. for each compared signal, if the signal is on the impacted signal list, checking if the signal is the fault location;
e. for each compared signal on the impacted signal list, if the signal is the fault location skipping to step h;
f. for each compared signal on the impacted signal list, if the signal is not the fault location adding the fanin signals of the signal to a next current signal list and storing the signal as the parent of the added fanin signals;
g. making the next current signal list the current signal list and returning to step b;
h. setting the fault locations at the path signal;
i. determining if the path signal has a parent signal;
j. if the path signal has a parent signal, using the parent a new path signal, storing the new path signal in a path list, and returning to step i for the new path signal;
k. if the path signal does not have a parent signal, outputting the path of impacted signals as the shortest fault path to the waveform viewer.

8. A computer-implemented method for calculation and display of a fault propagation path according to claim 1, wherein the step of displaying in a waveform viewer all signals in said fault path from said fault location to said observation point in order of their creation comprises:
displaying the signals in the timing domain, in a “stepladder” in a different color in the display to show how the fault moves forward from one signal to the next.

9. A computer-implemented method for calculation and display of a fault propagation path according to claim 1, wherein the step of displaying in a waveform viewer all signals in said fault path from said fault location to said observation point in order of their creation comprises using visual indicators including at least one of different color, different line thickness or different type of line or any other visual indicator.

10. A computer-implemented method for calculation and display of a fault propagation path comprising:
identifying with a computing device a fault location in an electrical circuit;
identifying with said computing device a plurality of observation points in the electrical circuit;
computing with said computing device fault paths from said fault location to at least two of said plurality of observation points; and
displaying in a waveform viewer all signals in said computed fault paths from said fault location to said at least two of said plurality of observation points in order of their creation.
